(19) United States
(12) Patent Application Publication
(10) Pub. No.: US 2012/0239323 A1
(43) Pub. Date: Sep. 20, 2012

(54) Virtual Machine Power Usage Estimations

(75) Inventors: Sean McGrane, Sammamish, WA (US); Aman Kansal, Issaquah, WA (US)

(73) Assignee: Microsoft Corporation, Redmond, WA (US)

(21) Appl. No.: 13/049,485

(22) Filed: Mar. 16, 2011

(51) Int. Cl. G06F 19/00; G01R 21/00

(52) U.S. Cl. 702/62

(57) ABSTRACT

Provided herein is power usage estimation that may be applied to computing devices. Further, the power usage estimation may be determined per each thread, process and/or program running on the computing device, such as, for example, a virtual machine. Power meters may be associated with individual components in a computing device, the sum of the power consumption of the computing components being equal to the total power consumption of the computing device. Metrics for usage by a process may be associated with each component, from which power consumption profiles based on component usage by a process may be created. Estimations of power usage may be used in contracting, billing, ranking, system control, priority, output and the like. Estimations of power usage may also include a power consumption “learning” phase and a way of incorporating previously disregarded base power usage into the estimate of power consumption by a process.

### BACKGROUND

As is well known, computing devices require power to operate. The power required for operation, however, is not a stable or set value. Computing devices, when turned on, may require large amounts of power to initiate processes. They may also have a baseline power associated with an idle state with no processes or threads running. Running a process on a computing device can tax one or more computing components associated with the computing device, increasing the power consumption. Further, computing devices may have ‘sleep’ modes or states which reduce the power consumption. In large server farms the amount of power required to run many computing devices may be extremely expensive and, more specifically, the power to operate particular processes may be extremely expensive. Owners of server farms charge users of the servers and various ways of charging users have been suggested.

Attempts have been made to charge users of computer resources in, for example, server farms and the like. One method known in the art for charging computer resource consumption is to estimate the amount of CPU usage from a particular process. This method, however, while providing a rough estimate of the usage of the computing device may be inaccurate and it may not provide a full picture of the usage of resources on the computing device. For example, certain processes may utilize only a small portion of the CPU but utilize asymmetric amounts of other components of the computing device. In addition, external factors, such as the amount of heat output by the CPU may cause a fan or other cooling device to pull more power, which would not necessarily be included in the cost of processing based solely on CPU usage. Another method for determining usage of a computing device is to place a power meter on the base board management controller (BMC). Placing a power meter on BMC provides a description of the power usage of the computing device, which may be useful if, for example, a single process is running on the computing device.

### SUMMARY

Provided herein is a power usage estimation that may be applied to computing devices. Further, the power usage estimation may be determined per each thread, process and/or program running on the computing device, such as, for example, a virtual machine. As used herein, a process generally describes a thread, a program operating on a computing device, a virtual machine, a process and the like. Estimations of power usage may be used in contracting, billing, ranking, system control, priority, output and the like. Estimations of power usage may also include a power consumption “learning” phase and a way of incorporating previously disregarded base power usage into the estimate of power consumption by a process.

In one embodiment, one or more power meters may be associated with computing components on a computing device. These computing components may include, for example, memory, I/O devices, processors, cores, DIMMs, network devices, graphics cards, disks, drives, fans, motherboards and the like. The power usage of each device may be monitored, along with a metric indicative of the usage of the device by a process.

Before a process is started, the power usage of each computing component may be monitored, logged, and the like. A process may initiate and the power usage of each component may again be monitored, stored, logged and the like. The process may operate at various other levels of usage of one or more computing components, and yet again the usage of the various devices may be monitored, logged, stored and the like. Each of this plurality of operations may be defined as operational states of the process. Accordingly, accurate representations and or profiles of power consumption for a process may be determined based on the computing component usage of the process.

In an embodiment, multiple processes may be running on the same computing device. Each process may have undergone or currently be undergoing a learning process whereby the power consumption of the process is known for operational states which have associated therewith, computing component usage. As such, the power consumption of each process may be unwound such that the information about power consumption usage of each process may be used in one or more ways.

In another embodiment monitoring the operational state (computing component usage) and power usage by a particular process may provide information, which can be used to prioritize and or decrease the usage of/by a particular process to reduce power consumption. Parties could, for example, agree that their usage is less important, and may receive, for example, a cheaper rate, a lower priority and the like. In such an embodiment, a computing device may be running multiple processes and may, for example, run out of CPU space, near overheating, or otherwise need to decrease the usage of one or more processes. If the power consumption profile of each process is known, the computing device may be able to scale back the usage by a process such that, for example, heat output may be reduced. The determination of which processes to slow or stop may be made based on any pre-determined scheme, such as, for example, importance, price, the relationship between consumption and CPU usage, heat output, mechanical or processing factors or any other computing device configurations.

In a further embodiment, virtual machines may be implemented on one or more servers in a server farm. The virtual machines may temporarily run on a first commuting device, and then run on another computing device at a different point in time. The power consumption provile of the virtual machine may be known and by monitoring metrics and power meters, the power consumption of a virtual machine may be monitored and an owner or user of the virtual machine may be charged according to the power consumption of the virtual machine. Further, such information may be gathered for any number of virtual machines running on any number of computing devices, thereby providing an efficient way to bill for computing device usage by a virtual machine.

In another embodiment, power associated with a base usage of a computing component may be dedicated for or otherwise associated with a process. The base usage of the dedicated/associated computing component may be determined and this base usage may be included in the total power consumption of the process.

### BRIEF DESCRIPTION OF THE DRAWINGS

FIG. 1 depicts an exemplary computing system 100.

FIG. 2 depicts an exemplary virtualization platform that can be used to generate virtual machines.

FIG. 3 depicts an alternative virtualization platform to that described above in FIG. 2.

FIG. 4 depicts a representation of a prior art power management on a computing device.

FIG. 5 depicts an exemplary computing system comprising power usage monitoring in accordance with the present disclosure.

FIG. 6 depicts a flowchart with a sample embodiment for determining a power profile of a process, program or virtual machine.

FIG. 7 depicts a flowchart for the determination of power consumption on a computing device by two or more processes.

FIG. 8 depicts a flowchart for an example embodiment of incorporating elements of base power into the power consumption associated with a process.

### DETAILED DESCRIPTION OF ILLUSTRATIVE EMBODIMENTS

It has been difficult to obtain accurate estimations of the power consumption of processes running on a computing device because neither the hardware, nor the software sufficiently solved the problem. In prior attempts at determining the power consumption of a process, the total power consumption was determined, a single base value for the entire computing device was determined and then when one or more processes ran on one or more CPUs, the increase in power consumption was associated with the processes and divided up between the running processes according to CPU usage. The CPU usage, however, is a poor measure of power consumption of every component on a computing device.

Described herein are computing devices, the computing device comprising computing components. Power meters may be attached to computing components such as processors, memories, disks, I/O devices, voltage regulators, fans and the like. Also described herein is using one or more virtual machines on a computing device having a plurality of power meters attached to computing components. A process running on an operating system, such as, for example, a hypervisor may receive information from each power meter attached to the various components. When one or more processes is operating on the computing device, the information from the power meters may be used in combination with information about the usage of a computing component (an operational state). In such an example, a computing device may be able to determine an instant power consumption of the virtual machine. As a further example, a series of data points representing the consumption of power of the various components when the process is in a plurality of operational states may be stored and the data may be manipulated in one or more ways to determine estimates of power consumption of a virtual machine at any and all virtual machine operational states, which are indicative of computing component usage levels. As such, an owner or user of a virtual machine may be billed based on their power consumption of the computing device in a more accurate fashion.

One of the problems associated with determining and billing power consumption based on computing component usage is the base power associated with components. In a normal computing device, there may be a base power that is associated with having the system powered on at all. This base power may be subtracted out of power consumption in some power consumption determination applications. It is possible, however, as disclosed herein to include more of the base power in a calculation associating power consumption with one or more processes. For example, it is possible to determine what portion of base power is attributable to a process and to thereby subtract base power formally included with the system base but attributable to the process from the base power of the computing system. As a further example, a virtual machine may be running on a computing device. The virtual machine may have designated memory, disks, cores, processors, or other computing components associated with, or reserved for, or otherwise dedicated to the virtual machine. If the resources associated with a virtual machine are known and the power consumption, including base consumption of the resources are known, it is possible to incorporate the base consumption of the dedicated resources with the power consumption value of the virtual machine. As such, power usage previously considered to be part of the base power will be attributable to a process.

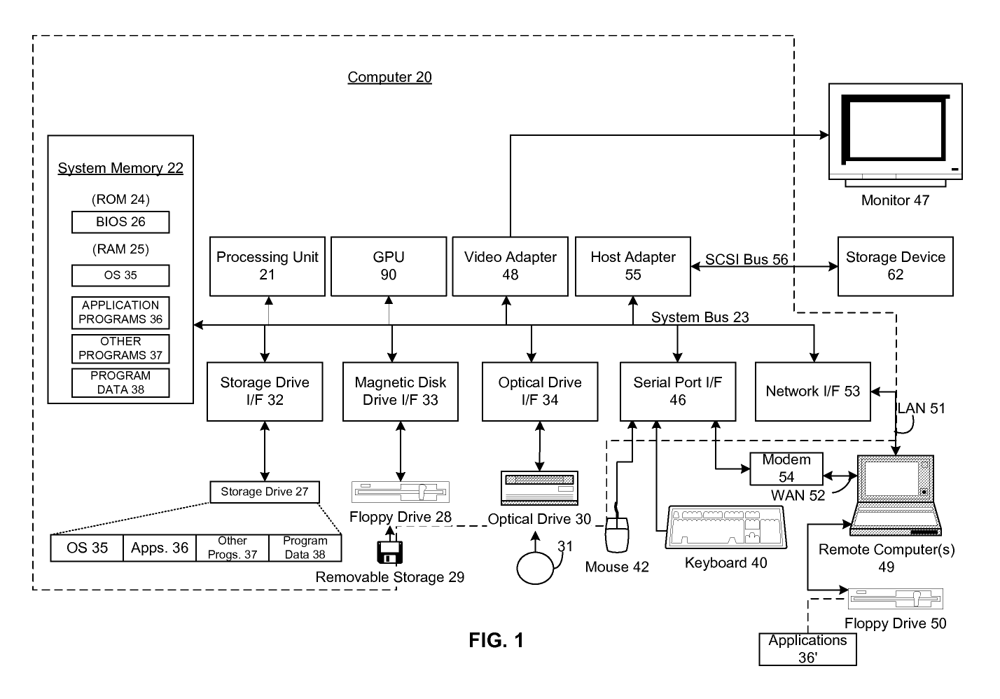

The disclosed subject matter may use one or more computer systems. FIG. 1 and the following discussion are intended to provide a brief general description of a suitable computing environment in which the disclosed subject matter may be implemented.

Processor(s) can be configured by instructions loaded from memory, e.g., RAM, ROM, firmware, and/or mass storage, embodying logic operable to configure the processor to perform a function(s). In an example embodiment, where circuitry includes a combination of hardware and software, an implementer may write source code embodying logic that is subsequently compiled into machine readable code that can be executed by hardware.

Embodiments may execute on one or more computer systems. FIG. 1 and the following discussion are intended to provide a brief general description of a suitable computing environment in which the disclosed subject matter may be implemented.

FIG. 1 depicts an example general purpose computing system. The general purpose computing system may include a conventional computer 20 or the like, including processing unit 21. Processing unit 21 may comprise one or more processors, each of which may have one or more processing cores. A multi-core processor, as processors that have more than one processing core are frequently called, comprises multiple processors contained within a single chip package.

Computer 20 may also comprise graphics processing unit (GPU) 90. GPU 90 is a specialized microprocessor optimized to manipulate computer graphics. Processing unit 21 may offload work to GPU 90. GPU 90 may have its own graphics memory, and/or may have access to a portion of system memory 22. As with processing unit 21, GPU 90 may comprise one or more processing units, each having one or more cores.

Computer 20 may also comprise a system memory 22, and a system bus 23 that communicative couples various system components including the system memory 22 to the processing unit 21 when the system is in an operational state. The system memory 22 can include read only memory (ROM) 24 and random access memory (RAM) 25. A basic input/output system 26 (BIOS), containing the basic routines that help to transfer information between elements within the computer 20, such as during start up, is stored in ROM 24. The system bus 23 may be any of several types of bus structures including a memory bus or memory controller, a peripheral bus, or a local bus, which implements any of a variety of bus architectures. Coupled to system bus 23 may be a direct memory access (DMA) controller 80 that is configured to read from and/or write to memory independently of processing unit 21. Additionally, devices connected to system bus 23, such as storage drive I/F 32 or magnetic disk drive I/F 33 may be configured to also read from and/or write to memory independently of processing unit 21, without the use of DMA controller 80.

The computer 20 may further include a storage drive 27 for reading from and writing to a hard disk (not shown) or a solid-state disk (SSD) (not shown), a magnetic disk drive 28 for reading from or writing to a removable magnetic disk 29, and an optical disk drive 30 for reading from or writing to a removable optical disk 31 such as a CD ROM or other optical media. The hard disk drive 27, magnetic disk drive 28, and optical disk drive 30 are shown as connected to the system bus 23 by a hard disk drive interface 32, a magnetic disk drive interface 33, and an optical drive interface 34, respectively. The drives and their associated computer-readable storage media provide non-volatile storage of computer readable instructions, data structures, program modules and other data for the computer 20. Although the example environment described herein employs a hard disk, a removable magnetic disk 29 and a removable optical disk 31, it should be appreciated by those skilled in the art that other types of computer readable media which can store data that is accessible by a computer, such as flash memory cards, digital video discs or digital versatile discs (DVDs), random access memories (RAMs), read only memories (ROMs) and the like may also be used in the example operating environment. Generally, such computer readable storage media can be used in some embodiments to store processor executable instructions embodying aspects of the present disclosure. Computer 20 may also comprise a host adapter 55 that connects to a storage device 62 via a small computer system interface (SCSI) bus 56.

A number of program modules comprising computer-readable instructions may be stored on computer-readable media such as the hard disk, magnetic disk 29, optical disk 31, ROM 24 or RAM 25, including an operating system 35, one or more application programs 36, other program modules 37, and program data 38. Upon execution by the processing unit, the computer-readable instructions cause actions described in more detail below to be carried out or cause the various program modules to be instantiated. A user may enter commands and information into the computer 20 through input devices such as a keyboard 40 and pointing device 42. Other input devices (not shown) may include a microphone, joystick, game pad, satellite disk, scanner or the like. These and other input devices are often connected to the processing unit 21 through a serial port interface 46 that is coupled to the system bus, but may be connected by other interfaces, such as a parallel port, game port or universal serial bus (USB). A display 47 or other type of display device can also be connected to the system bus 23 via an interface, such as a video adapter 48. In addition to the display 47, computers typically include other peripheral output devices (not shown), such as speakers and printers.

The computer 20 may operate in a networked environment using logical connections to one or more remote computers, such as a remote computer 49. The remote computer 49 may be another computer, a server, a router, a network PC, a peer device or other common network node, and typically can include many or all of the elements described above relative to the computer 20, although only a memory storage device 50 has been illustrated in FIG. 1. The logical connections depicted in FIG. 1 can include a local area network (LAN) 51 and a wide area network (WAN) 52. Such networking environments are commonplace in offices, enterprise wide computer networks, intranets and the Internet.

When used in a LAN networking environment, the computer 20 can be connected to the LAN 51 through a network interface or adapter 53. When used in a WAN networking environment, the computer 20 can typically include a modem 54 or other means for establishing communications over the wide area network 52, such as the INTERNET. The modem 54, which may be internal or external, can be connected to the system bus 23 via the serial port interface 46. In a networked environment, program modules depicted relative to the computer 20, or portions thereof, may be stored in the remote memory storage device. It will be appreciated that the network connections shown are exemplary and other means of establishing a communications link between the computers may be used. Moreover, while it is envisioned that numerous embodiments of the present disclosure are particularly well-suited for computerized systems, nothing in this document is intended to limit the disclosure to such embodiments.

In an embodiment where computer 20 is configured to operate in a networked environment, OS 35 is stored remotely on a network, and computer 20 may netboot this remotely-stored OS rather than booting from a locally-stored OS. In an embodiment, computer 20 comprises a thin client where OS 35 is less than a full OS, but rather a kernel that is configured to handle networking and display output, such as on monitor 47.

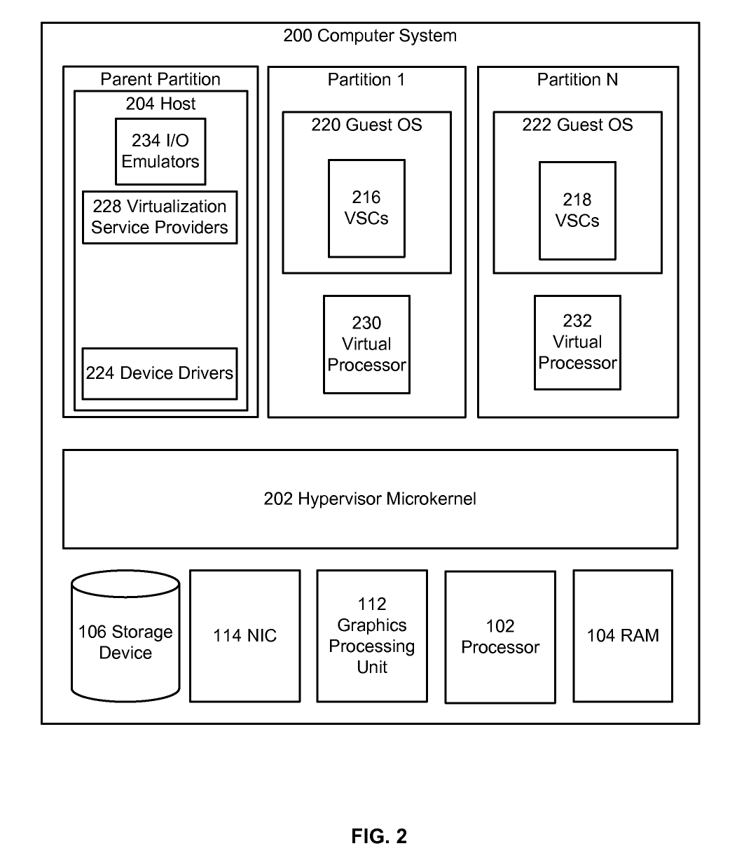

The computer system 20 of FIG. 1 may have one or more virtual machines operating on the hardware and which may control and utilize the hardware described in FIG. 1. FIG. 2 depicts a virtualization platform that may run on a computing device such as the device shown in FIG. 1. In one embodiment one or more virtual machines may operate on one or more computing devices in, for example, a server farm. Virtual machines may monitor or may be monitored such that the power consumption of the virtual machine, regardless of what hardware it is running on, may be determined. It is therefore possible to bill based on the power consumption of the virtual machine regardless of what hardware the virtual machine runs on, or what portion of the hardware the virtual machine utilizes.

Turning to FIG. 2, illustrated is an exemplary virtualization platform that can be used to generate virtual machines. In this embodiment, hypervisor microkernel 202 can be configured to control and arbitrate access to the hardware of computer system 200, which may be computer 20, referring back to FIG. 1. Hypervisor microkernel 202 can generate execution environments called partitions such as child partition 1 through child partition N (where N is an integer greater than 1). Here, a child partition is the basic unit of isolation supported by hypervisor microkernel 202. Hypervisor microkernel 202 can isolate processes in one partition from accessing another partition's resources. Each child partition can be mapped to a set of hardware resources, e.g., memory, devices, processor cycles, etc., that is under control of the hypervisor microkernel 202. In embodiments hypervisor microkernel 202 can be a stand-alone software product, a part of an operating system, embedded within firmware of the motherboard, specialized integrated circuits, or a combination thereof.

Hypervisor microkernel 202 can enforce partitioning by restricting a guest operating system's view of the memory in a physical computer system. When hypervisor microkernel 202 instantiates a virtual machine, it can allocate pages, e.g., fixed length blocks of memory with starting and ending addresses, of system physical memory (SPM) to the virtual machine as guest physical memory (GPM). Here, the guest's restricted view of system memory is controlled by hypervisor microkernel 202. The term guest physical memory is a shorthand way of describing a page of memory from the viewpoint of a virtual machine and the term system physical memory is shorthand way of describing a page of memory from the viewpoint of the physical system. Thus, a page of memory allocated to a virtual machine will have a guest physical address (the address used by the virtual machine) and a system physical address (the actual address of the page).

A guest operating system may virtualize guest physical memory. Virtual memory is a management technique that allows an operating system to over commit memory and to give an application sole access to a contiguous working memory. In a virtualized environment, a guest operating system can use one or more page tables to translate virtual addresses, known as virtual guest addresses into guest physical addresses. In this example, a memory address may have a guest virtual address, a guest physical address, and a system physical address.

In the depicted example, parent partition component, which can also be also thought of as similar to domain 0 of Xen's open source hypervisor can include a host 204. Host 204 can be an operating system (or a set of configuration utilities) and host 204 can be configured to provide resources to guest operating systems executing in the child partitions 1-N by using virtualization service providers 228 (VSPs). VPSs 228, which are typically referred to as back-end drivers in the open source community, can be used to multiplex the interfaces to the hardware resources by way of virtualization service clients (VSCs) (typically referred to as front-end drivers in the open source community or paravirtualized devices). As shown by the figures, virtualization service clients execute within the context of guest operating systems. However, these drivers are different than the rest of the drivers in the guest in that they may be supplied with a hypervisor, not with a guest. In an exemplary embodiment the path used to by virtualization service providers 228 to communicate with virtualization service clients 216 and 218 can be thought of as the virtualization path.

As shown by the figure, emulators 234, e.g., virtualized IDE devices, virtualized video adaptors, virtualized NICs, etc., can be configured to run within host 204 and are attached to resources available to guest operating systems 220 and 222. For example, when a guest OS touches a memory location mapped to where a register of a device would be or memory mapped device, microkernel hypervisor 202 can intercept the request and pass the values the guest attempted to write to an associated emulator. Here, the resources in this example can be thought of as where a virtual device is located. The use of emulators in this way can be considered the emulation path. The emulation path is inefficient compared to the virtualized path because it requires more CPU resources to emulate device than it does to pass messages between VSPs and VSCs. For example, the hundreds of actions on memory mapped to registers required in order to write a value to disk via the emulation path may be reduced to a single message passed from a VSC to a VSP in the virtualization path.

Each child partition can include one or more virtual processors (230 and 232) that guest operating systems (220 and 222) can manage and schedule threads to execute thereon. Generally, the virtual processors are executable instructions and associated state information that provide a representation of a physical processor with a specific architecture. For example, one virtual machine may have a virtual processor having characteristics of an Intel x86 processor, whereas another virtual processor may have the characteristics of a PowerPC processor. The virtual processors in this example can be mapped to processors of the computer system such that the instructions that effectuate the virtual processors will be backed by processors. Thus, in an embodiment including multiple processors, virtual processors can be simultaneously executed by processors while, for example, other processor execute hypervisor instructions. The combination of virtual processors and memory in a partition can be considered a virtual machine.

Guest operating systems (220 and 222) can be any operating system such as, for example, operating systems from Microsoft®, Apple®, the open source community, etc. The guest operating systems can include user/kernel modes of operation and can have kernels that can include schedulers, memory managers, etc. Generally speaking, kernel mode can include an execution mode in a processor that grants access to at least privileged processor instructions. Each guest operating system can have associated file systems that can have applications stored thereon such as terminal servers, e-commerce servers, email servers, etc., and the guest operating systems themselves. The guest operating systems can schedule threads to execute on the virtual processors and instances of such applications can be effectuated.

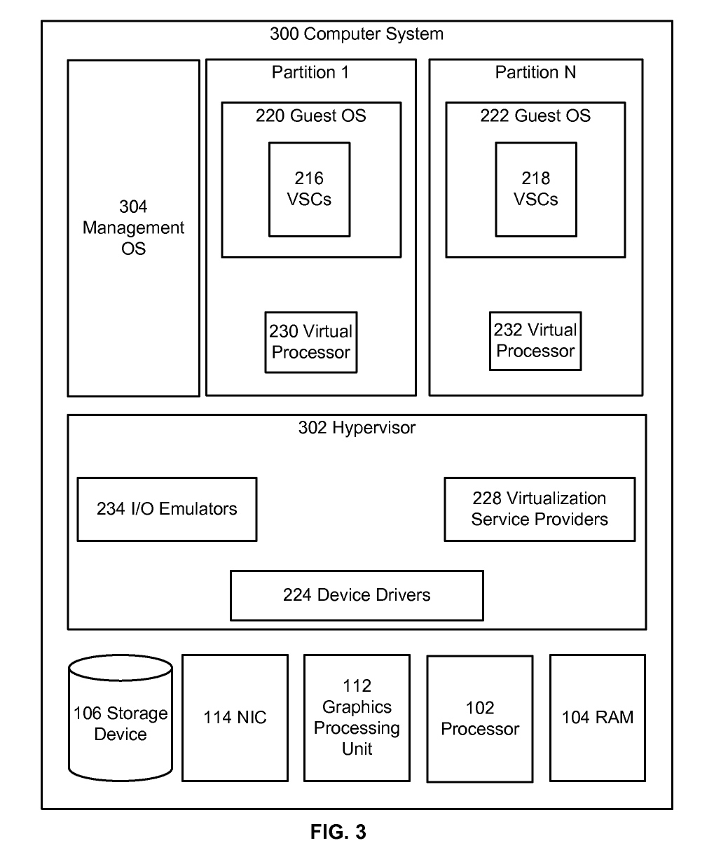

Referring now to FIG. 3, it illustrates an alternative virtualization platform to that described above in FIG. 2. FIG. 3 depicts similar components to those of FIG. 2; however, in this example embodiment hypervisor 302 can include a microkernel component and components similar to those in host 204 of FIG. 2 such as the virtualization service providers 228 and device drivers 224, while management operating system 304 may contain, for example, configuration utilities used to configure hypervisor 302. In this architecture, hypervisor 302 can perform the same or similar functions as hypervisor microkernel 202 of FIG. 2; however, in this architecture hypervisor 304 can be configured to provide resources to guest operating systems executing in the child partitions. Hypervisor 302 of FIG. 3 can be a stand alone software product, a part of an operating system, embedded within firmware of the motherboard or a portion of hypervisor 302 can be effectuated by specialized integrated circuits.

In the computing world, server farms are becoming larger both in number and in the processing power associated with each farm. At these server farms, threads, virtual machines, processes and programs run on one or more computing devices. It is desirable to charge those owners and/or users of processes based on their usage of one or more computing devices. Initial attempts at charging for usage involved processor power, but it may be more useful and accurate to charge based on the power consumption of a process because electricity and heat (cooling) are some expensive elements of a server farm, and because the electric costs may fluctuate, and the fluctuation if monitored, can be passed on to those whose processes require heavy power consumption.

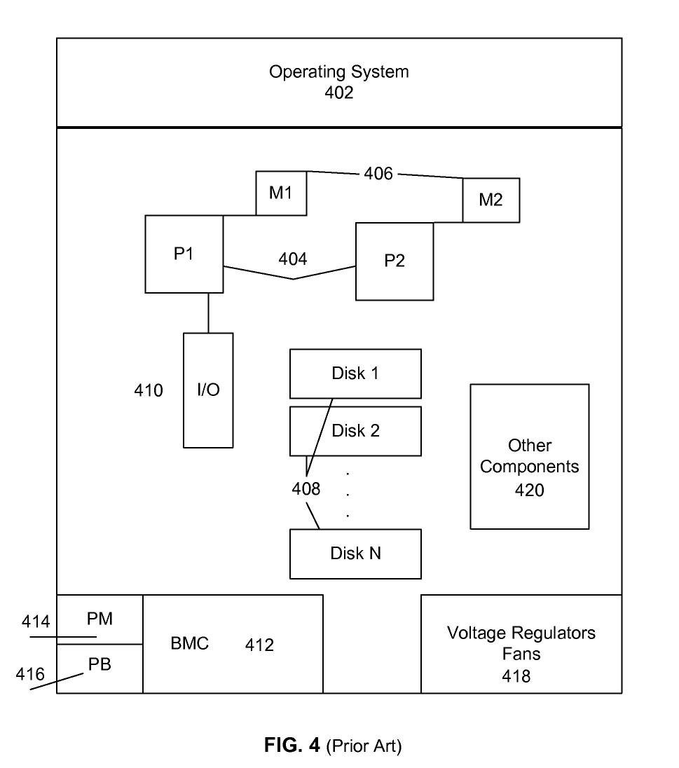

FIG. 4 depicts a system that was used in prior art attempts at determining the power consumption of a process running on a computing device. Early attempts merely measured the usage of CPU 404 and then associated the percentage power usage with whatever the percentage usage of the CPU 404 was. As depicted, there may be one or more processors which may be called a CPU, or a processor throughout this document and which may include processor 102 as described above with respect to FIG. 1. Although only two processors are depicted in FIG. 4, the number of processors on a computing device is not limited to two and this figure is not limiting in any way.

Determining power usage of a process after measuring only the usage of CPU 404 has several problems. For example, it ignores power consumed by idle processes, the portion of the base power attributable to the process when it is running, and it is not a fair representation of percentage usage of the other computing components, such as, for example, Memory 406, I/O device 410, voltage regulators and fans 418, disks 1-N 408, or any other computing component 420 which includes but is not limited to graphics cards, mother boards, and network cards, by a process. Further, it is difficult to determine the power usage by a single processes when there are multiple processes running.

Later attempts at determining the power usage of a process running on a computing device incorporate a Power Meter, shown as PM 414 into a computing device. These system may have also included a baseboard management controller BMCs 412 and power budgets PB 416. Knowing the total power usage of a computing device may provide further information and thus be a better way to measure usage. This prior art, however, was limited in several ways. If more than one process is running on a computing device, the PM 414 merely determines the total system power and CPU usage merely divides up the power according to the percentage usage of the processor. Further, this method neglects the power consumption of individual computing components and the amount of power required per component when the component us used by a process. Base power consumption is also lost in system idle processes and may not be as easily associated with a process running on a computing device.

As used herein, memory 406 may be any memory and may include RAM 104, ROM, storage devices 106 and removable storage devices 118 as noted above with respect to FIG. 1. Although only two Memory units are depicted in FIG. 4, this is in no way limiting and the number of memory units is not limited to two. I/O devices 410 may be any peripheral device, display device, keyboard, mouse, controller, network card, modem wireless device, bluetooth or the like including all I/O devices 116 described above with respect to FIG. 1.

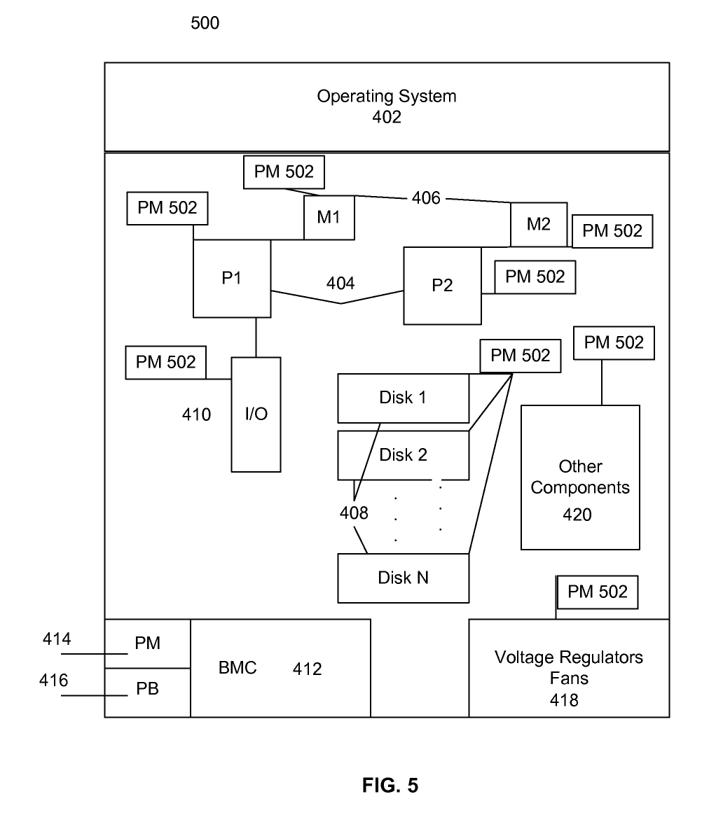

FIG. 5 depicts a computing device in accordance with the present disclosure wherein each of the components of the depicted computing device, including processors 404, I/O devices 410, memories 406, disks 408, BMC 412, voltage regulators and fans 418 and other components 420 may have associated therewith, power meters 502. These power meters may measure the power consumption of each of the computing components in the computing device. These power meters may also send and receive information from other components in the computing device. For example, the information determined by the power meters 502 may be sent to a processor 404, stored in a memory 406 or any other component 420 or otherwise used in any other process or program. The information matching to one or more hardware components may work on or with one or more power management programs operating on a processor, in a hypervisor, on a virtual machine or associated with any other process.

The information from a power meter may be used in a number of ways. For example, when a process initiates, a “learning” process may take place. The power consumption of each component may be determined during, for example, startup, idle process, 1% CPU usage, 2% CPU usage, 3% CPU usage and so forth up to 100% CPU usage, each of which represents an operational state. As such it may be possible to determine a profile of estimates of the consumption of each component by a process. Further, the learning may be an ongoing process whereby when a process is utilizing one or more resources, where the utilization may be associated with a power consumption value and that information may be stored in a memory.

In the example above, the learning process was associated with the CPU usage. This example is in no way intended to be limited. The learning process may be associated with the usage of any other computing component on a computing device. This usage may be known as a metric. One metric may be CPU usage. Another metric, for example, may be the amount of disk space, the throughput on a read/write process, the speed of a fan, the usage of an I/O device, the bandwidth of a connection, the usage of a graphics process or any other manner of determining an amount of usage of any component in a computing device described above.

Power meter PM 502 may be any type of power meter known in the art that may be used for the detection of the consumption of power of a computing device or component. For example, the PM 502 may measure power in Watts, Joules or other suitable units and may operate based on the incoming current or voltage or in any other manner known to those having skill in the art. PM 502 may be associated with a single component or a series of components and may provide information to processors, operating systems 402, hypervisor 302 or any other component in computing device 500.

Operating system 402 may manage one or more aspects of the computing device and may be used in one or more ways to monitor, detect, store and calculate the power usage and metric usage of each computing component. In addition, the operating system may receive information from one or more computing components, such as, for example, Power Meters 502, which the computing device may use in one or more ways to determine power consumption of a device, components, system or process. The operating system may have associated therewith a hypervisor, the hypervisor configured to receive, store, send, manipulate and calculate data. As one example, the hypervisor may receive information about the power usage of virtual machines and may store data related to the power usage of the virtual machines. Accordingly, profiles of the power usage for each virtual machine may be determined. Accordingly, data associated with the usage of the hypervisor and/or the CPU may be received by the hypervisor and/or processor and the hypervisor and/or CPU may associate the received data with a power consumption value. The power consumption value may be used to bill owners and users of virtual machines, processes, programs, threads and the like.

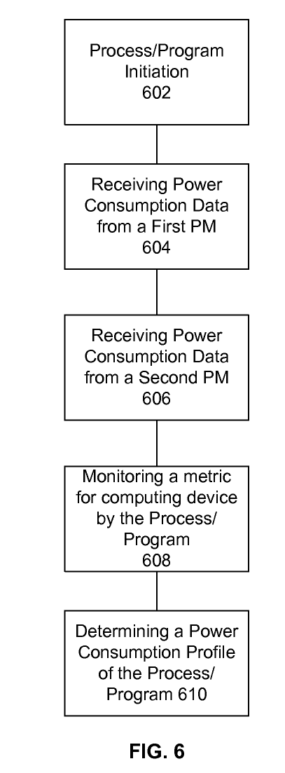

FIG. 6 depicts a flowchart for power consumption by a process on a computing device. At step 602, a process may initiate on a computing device such as computing device 100. The computing device may have already been operational and one or more power meters may determine the power consumption on components on the computing device associated with the power meter. A sum of the powers, which could be, for example, the total power consumption by the computing device may define a base power when no processes are running on a device and the device is in idle. The same power meters may determine the power consumption of one or more components of the computing device upon process initiation 602.

At 604, power consumption data may be received from a first power meter. The first power meter may have measured the power consumption of one or more computing components. As one example, this may be the data associated with the initiation of the process, and/or it may be data associated with the usage of the power meter when the process is an idle phase, and/or it may be the power consumption of one or more computing components when the process is at any other level of component usage. As a further example, the power meter data may be associated with an operational state, which can be the percentage usage of any other computing component and a metric associated with the component. For example, a metric associated with a component may be the percentage usage/bandwidth/and/or speed of the I/O circuit, the percentage throughput in read/write process, percentage or amount of usage of a memory, the speed of a fan, the percentage usage of a disk or drive, the number of disks or drives used, the percentage usage of a graphics processing unit, of a core, or the amount of usage of any other component in a computing device. In an embodiment, the power meter data 604 will be associated with a metric. Thus, the received power consumption data from a first power meter will be associated with a metric, where the metric is associated with a usage of a computing component.

At step 606, power consumption may be received from a second power meter. Similar to the consumption data from a first power meter above, the second power meter may have measured the power consumption of one or more computing components. As one example, this may be the data associated with the initiation of the process, and/or it may be data associated with the usage of the power meter when the process is an idle phase, and/or it may be the power consumption of one or more computing components when the process is at any other level of CPU usage. As a further example, the power meter data may be associated with an operation state which may be the percentage usage of any other computing component and a metric associated with the component. For example, a metric associated with a component may be the percentage usage/bandwidth/and/or speed of the I/O circuit, the percentage throughput in read/write process, percentage or amount of usage of a memory, the speed of a fan, the percentage usage of a disk or drive, the number of disks or drives used, the percentage usage of a graphics processing unit, of a core, or the amount of usage of any other component in a computing device. In an embodiment, the power meter data 606 will be associated with a metric. Thus, the received power consumption data from a second power meter will be associated with a metric, where the metric is associated with a usage of a computing component.

At step 608, the metric as discussed above with respect to steps 604 and 606 may be associated with the power meter data for the data received from both power meters. As one example, upon initiation of a process, two power meters, a first associated with a CPU and the second associated with a disk measure the consumption of the respective computing components. As the power profile is measured and stored, CPU usage, the metric in this example is monitored. Thus, the usage of each component and the metric may be combined into a power consumption profile 610 for the startup of a process or process. As will be understood, it need not be initiation of a process alone, the computing components are for example only and not limiting: any component may be monitored, and the metric is for example only, any other metric associated with the usage of any component may also be used in determining a power consumption profile of the process at 610.

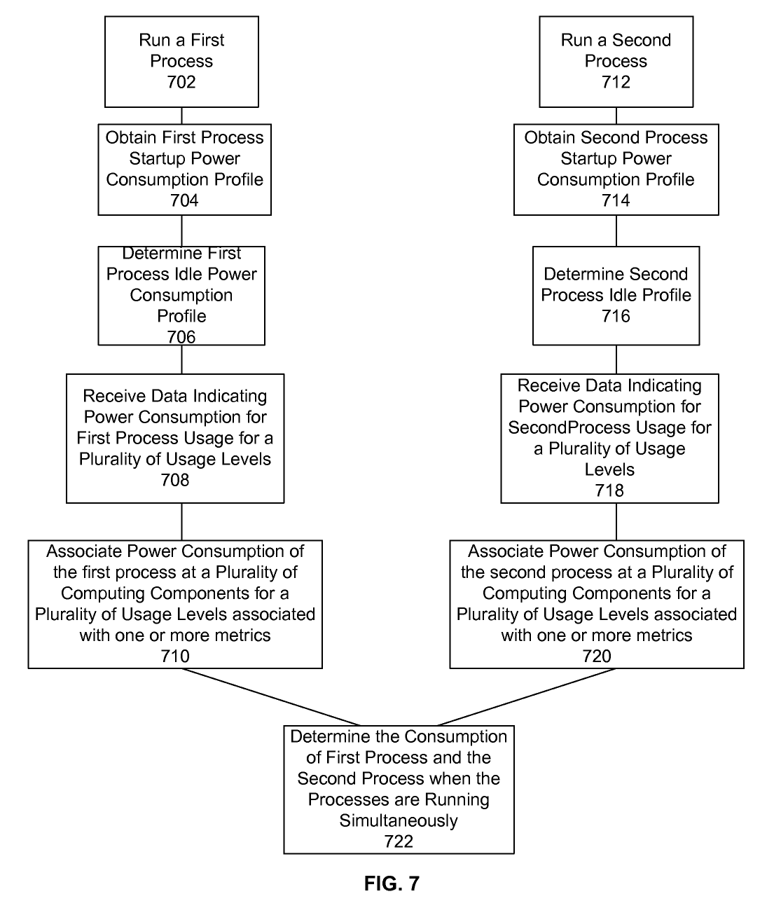

FIG. 7 depicts a flowchart for the determination of power consumption on a computing device by two or more processes. It should be noted that while FIG. 7 depicts these actions being performed in parallel, such a structure is in no way necessary. For example, a first process may initiate and be associated with a power consumption profile before a second process initiates. Further, the two may run in parallel, or the various steps may overlap in any way.

At step 702, a first process may initiate. The process, as described above may be anything running on a computing device, including but not limited to, a virtual machine. At step 704, a power profile may be determined for the startup of the first process. As discussed with respect to FIG. 6, this profile may be determined using two or more power meters and may include a metric associated with one or more components of the computing device. At step 706, a power profile may be determined for the first process idle state. As discussed with respect to FIG. 6, this profile may be determined using two or more power meters and may include a metric associated with one or more components of the computing device.

It should be noted with respect to an idle state of a computing device, that the term idle state is generic and intended to encompass the various states of not running a thread or process or idle that a processor or a computing device may be in. For example, this could be the state of user usage of any component, according to a metric associated with the component. As another example, it may be an active state where the processor is not running a thread but is prepared to run a thread, a sleep state, any one of the C-states, any other process idle or component state or any other type of low usage or power consumption state.

At step 708, a power profile may be determined for the first process at a plurality of usage levels of one or more components. As discussed above with respect to FIG. 6, this profile may be determined using two or more power meters and may include one or more metrics associated with one or more components of the computing device. At step 710, the data associated with the startup, idle and component usage states may be used to determine a power consumption profile. Using the profile at 710, it may be able to associate the power consumption of the first process even if there are multiple other processes running on one or more components of the computing device. For example, using the first process profile and receiving information about one or more metrics associated with the first process, it may be possible to determine overall power consumption by the process on the computing device. As a further example, it may be possible to determine the power consumption of a first virtual machine when there are a plurality of virtual machines, or when there is a virtual machine and a plurality of other processes.

At step 712, a second process may initiate. The process, as described above may be anything running on a computing device, including but not limited to, a virtual machine. At step 714, a power profile may be determined for the startup of the second process. As discussed with respect to FIG. 6, this profile may be determined using two or more power meters and may include a metric associated with one or more components of the computing device. At step 716, a power profile may be determined for the second process idle state. As discussed with respect to FIG. 6, this profile may be determined using two or more power meters and may include a metric associated with one or more components of the computing device.

At step 718, a power profile may be determined for the second process at a plurality of usage levels of one or more components. As discussed above with respect to FIG. 6, this profile may be determined using two or more power meters and may include one or more metrics associated with one or more components of the computing device. At step 720, the data associated with the startup, idle and component usage states may be used to determine a power consumption profile. Using the profile at 720, it may be able to associate the power consumption of the second process even if there are multiple other processes running on one or more components of the computing device. For example, using the second process profile and receiving information about one or more metrics associated with the second process, it may be possible to determine overall power consumption by the process on the computing device. As a further example, it may be possible to determine the power consumption of a second virtual machine when there are a plurality of virtual machines, or when there is a virtual machine and a plurality of other processes.

At step 722, in an embodiment, the power consumption of a plurality of processes may be determined simultaneously. As one example, learning the power consumption profile of a process according to FIGS. 6 and 7 may be a one time event that occurs when a new process is introduced to a computing device. As a further example, it may be an ongoing event which continually updates each time information about the power consumption is received.

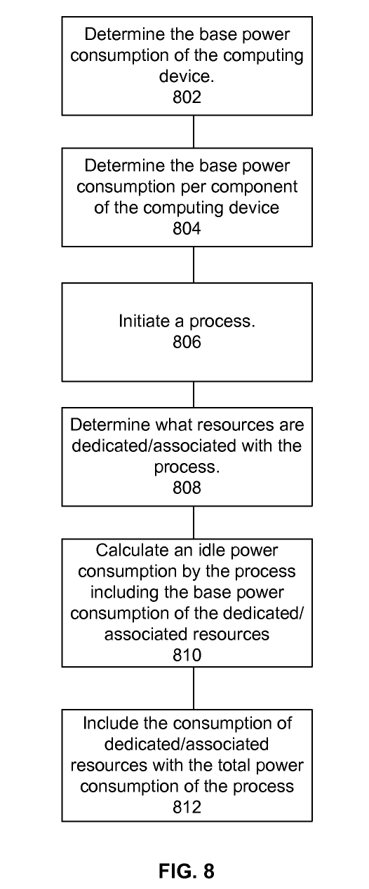

FIG. 8 depicts a flowchart for an example embodiment of incorporating elements of base power into the power consumption associated with a process. At step 802, the base power consumption of the computing device may be determined. This base power may be the power required in an idle state, after start up, by a computing device without any virtual machines or process running on it. The idle state may be any idle state including sleep states and C-states or at an active state where the processor is prepared to run code. As a further example, base power consumption is the consumption of power by the device associated with merely having the device turned on and in a ready state for code, or one or more processes to run on it. These states may generally be defined as operational states.

At step 804, the base power may be divided up on a per component base. For example, individual power meters 502 as described above with respect to FIG. 5 may be used to determine the consumption of one or more devices at an idle state. At step 806, a process may initiate. As discussed above, this may be a virtual machine, a threat, running a program or code or the like. At 808, information associated with the usage of computing components and computing resources are associated with the process initiated at step 806. For example, memory space, disk space, I/O usage and the like may be associated in part or in whole with process 806. At step 810, the base power consumption of the components associated with process 806 may be determined. At step 812, the base power consumption of the components and or resources associated with or otherwise dedicated to process 806 may be included in the total power consumption calculation of the process 806 when a power consumption profile, such as the power consumption profiles described with respect to FIGS. 6 and 7 is determined.

It should be noted that when a power consumption profile is associated with a thread, process and the like, it is possible to record the power consumption of that thread, process or the like over time. The determination of the amount of power used over time by a process can be used in any number of ways, including but not limited to billing, determining priority, determining heat dissipation, heat localization, acceptable percentage usage of a computing device or of a particular component and the like.

It should be understood that the configurations and/or approaches described herein are exemplary in nature, and that these specific embodiments or examples are not to be considered limiting. The specific routines or methods described herein may represent one or more of any number of processing strategies. As such, various acts illustrated may be performed in the sequence illustrated, in other sequences, in parallel, or the like. Likewise, the order of the above-described processes may be changed.

Additionally, the subject matter of the present disclosure includes combinations and sub-combinations of the various processes, systems and configurations, and other features, functions, acts, and/or properties disclosed herein, as well as equivalents thereof.

What is claimed:

1. A method for calculating a power usage value by one or more processes operating on a computing device, the method comprising:
operating a first process in a first operational state;
measuring one or more metrics, each metric associated with a respective computing component, each metric being indicative of the use of the associated computing component by the first process;
receiving from a first power meter associated with a first computing component, data associated with the power consumption of the one or more processes;
receiving from a second power meter associated with a second computing component, data associated with the power consumption of the one or more processes; and
based on the metric, the data from the first power meter, and the data from the second power meter, calculating a first power consumption value.

2. The method of claim 1 further comprising determining the first power consumption value of the first process in a plurality of operational states of the first process.

3. The method of claim 2 further comprising: storing in a database the power consumption values of the computing device by the first process.

4. The method of claim 1 further comprising:
running a second process in a second operational state;
monitoring the one or more metrics, each metric associated with a respective computing component, each metric being indicative of the use of the associated computing component by the second process;
receiving, from the first power meter associated with a first computing component, data associated with the power consumption of the one or more processes;
receiving from the second power meter associated with a second computing component, data associated with the power consumption of the one or more processes; and
based on the metric, the data from the first power meter, and the data from the second power meter, calculating a second power consumption value.

5. The method of claim 4 further comprising determining the second power consumption value in a plurality of operational states of the second process.

6. The method of claim 4 wherein the first and second processes comprise virtual machines.

7. The method of claim 1 further comprising associating one or more computing components with the first process and including a base power attributed to the one or more computing components with the first power consumption value.

8. The method of claim 2 wherein the processor determines an estimate of power consumption by the first process over a period of time.

9. The method of claim 4 wherein the first power consumption values for the first process and the second power consumption value for the second process are used to determine operational configurations of the computing device.

10. A system for determining a power consumption value by one or more processes operating on a computing device, the system comprising;
a first computing component associated with a first power meter;
a second computing component associated with a second power meter;
at least one processor configured to determine the power consumption value of a first process operating on the computing device based on the consumption of power by the first process on the first computer component as measured by the first power meter and the consumption of power by the first process on the second computer component as measured by the second power meter.

11. The system of claim 10 wherein the at least one processor is configured to determine the first power consumption value for a range of operational states of the first process.

12. The system of claim 10 further comprising the at least one processor configured to determine the power consumption of a second process running on the computing device based on the consumption of power by the second process on the first computing component as measured by the first power meter and the consumption of power by the second process on the second computer component as measured by the second power meter.

13. The system of claim 12 wherein the at least one processor is configured to determine the second power consumption value for a range of operational states of the second process.

14. The system of claim 11 further comprising a database configured to store data associated with the power consumption values for a range of operational states of the first and second processes and wherein the stored data is used to determine power usage by the first process and the second process when both processes are running on the at least one processor.

15. The system of claim 12 wherein the first process and the second process are virtual machines.

16. A computer readable storage medium having stored thereon instructions configured to run on a processor, said instructions comprising instructions for:
running a first process;
monitoring the one or more metrics, each metric associated with a respective computing component, each metric being indicative of the use of the associated computing component by the first process;
receiving from a first power meter, data associated with the power requirements of the first process;
receiving from a second power meter, data associated with the power requirements of the first process; and
based on the metric, the data from the first power meter, and the data from the second power meter, calculating a first power consumption value.

17. The computer readable storage medium of claim 16 further comprising determining the first power consumption value of the first process across a range of operational states of the first process.

18. The computer readable storage medium of claim 16 further comprising:
running a second process on the at least one processor;
monitoring the one or more metrics, each metric associated with a respective computing component, each metric being indicative of the use of the associated computing component by the second process;
receiving, from the first power meter, data associated with the power requirements of the second process;
receiving from the second power meter, data associated with the power requirements of the second process; and
based on the metric, the data from the first power meter, and the data from the second power meter, calculating a second power consumption value.

19. The computer readable storage medium of claim 18 further comprising determining a second power consumption value across a range of operational states of the second process.

20. The computer readable storage medium of claim 18 wherein the first and second processes are virtual machines.
